(19) United States
(12) Patent Application Publication
(10) Pub. No.: US 2026/0150461 A1
(43) Pub. Date: May 28, 2026

(54) MANUFACTURING METHOD OF DISPLAY DEVICE, AND ELECTRONIC DEVICE INCLUDING DISPLAY DEVICE

(71) Applicant: Samsung Display Co., Ltd., Yongin-Si (KR)

(72) Inventors: Seul-Ki KIM, Yongin-si (KR); YEEUN KANG, Yongin-si (KR); Seung Rae KIM, Yongin-si (KR); Hyun KIM, Yongin-si (KR); Jin-Won LEE, Yongin-si (KR)

(21) Appl. No.: 19/177,651

(22) Filed: Apr. 14, 2025

(30) Foreign Application Priority Data
Jul. 26, 2024 (KR) 10-2024-0099555

(51) Int. Cl. H10H 29/39; H10H 29/01; H10H 29/37; H10H 29/41; H10H 29/45; H10K 59/12; H10K 59/122; H10K 59/123; H10K 59/124; H10K 59/127; H10K 59/80; H10K 102/00

(52) U.S. Cl. CPC H10H 29/39; H10H 29/012; H10H 29/37; H10H 29/41; H10H 29/45; H10K 59/1201; H10K 59/122; H10K 59/123; H10K 59/124; H10K 59/1275; H10K 59/8722; H10K 2102/351

(57) ABSTRACT

A display device includes a display area having a plurality of pixels and a non-display area surrounding the display area, and the display device comprises a transistor located on a first substrate in the display area, a pixel electrode connected to the transistor, a light emitting member on the pixel electrode, a common electrode on the light emitting member, a planarization layer having a substantially uniform thickness and located between the transistor and the pixel electrode in the display area, a pixel defining layer on the pixel electrode, and a dam located on the first substrate in the non-display area. The dam may include a lower layer including a same layer as the planarization layer and an upper layer including a same layer as the pixel defining layer, and the pixel defining layer may have a separation opening located between two adjacent pixels of the plurality of pixels.

### CROSS-REFERENCE TO RELATED APPLICATION

This application claims priority to and the benefit of Korean Patent Application No. 10-2024-0099555 filed on Jul. 26, 2024 in the Korean Intellectual Property Office, the entire contents of which are incorporated herein by reference.

### BACKGROUND

### 1. Field

The present disclosure relates to a display device, a manufacturing method of the display device, and an electronic device including the display device.

### 2. Description of the Related Art

A display device includes a liquid crystal display (LCD), a plasma display panel (PDP), an organic light emitting diode device (OLED device), a field emission display (FED), and an electrophoretic display device.

A light emitting display device is gaining attention as a next-generation display device due to advantages, such as a wide viewing angle, a fast response speed, and low power consumption as well as being lightweight and thin.

For manufacturing the light emitting display device, photomasks are used in the photolithography process. However, as the cost of photomasks is high, continuous efforts have been made to reduce the number of photolithography processes.

In addition, as high-resolution display devices are used recently, the size of each pixel has decreased and the distance between adjacent pixels has been narrowed.

### SUMMARY

Embodiments of the present disclosure provide a display device, a manufacturing method of the display device, and an electronic device including the display device that are capable of preventing lateral current leakage in a high-resolution display device and reducing manufacturing costs.

However, the problem to be solved by the embodiments is not limited to the above-described problem, and can be variously extended within the scope of the technical spirit included in the embodiments.

According to an embodiment, a display device includes a display area having a plurality of pixels and a non-display area surrounding the display area, and the display device comprises a transistor located on a first substrate in the display area, a pixel electrode connected to the transistor, a light emitting member on the pixel electrode, a common electrode on the light emitting member, a planarization layer having a substantially uniform thickness and located between the transistor and the pixel electrode in the display area, a pixel defining layer on the pixel electrode, and a dam located on the first substrate in the non-display area. The dam may include a lower layer including a same layer as the planarization layer and an upper layer including a same layer as the pixel defining layer, and the pixel defining layer may have a separation opening located between two adjacent pixels of the plurality of pixels.

The non-display area may include a pad region including a pad portion, and the planarization layer may be removed in the pad region.

A first thickness of the planarization layer in the display area may be substantially equal to a second thickness of the lower layer of the dam, and a third thickness of the pixel defining layer in the display area may be substantially equal to a fourth thickness of the upper layer of the dam.

A first width of the lower layer of the dam may be greater than a second width of the upper layer of the dam, and a sidewall of the lower layer of the dam may include two portions having different slopes.

The display device may further include a sealant located between the dam and the pad region on the first substrate.

The planarization layer may not be located under the sealant.

The display device may further include a second substrate bonded to the first substrate through the sealant and opposite to the first substrate.

The display device may further include a separation pattern separated from the common electrode and located in the separation opening.

The separation pattern may further include a portion separated from the light emitting member.

The separation opening may be formed in a portion of the planarization layer.

According to an embodiment, a manufacturing method of a display device, that includes a display area having a plurality of pixels and a non-display area surrounding the display area, comprises forming a planarization layer on the transistor in the display area and a preliminary lower layer of a dam in the non-display area, forming a pixel electrode connected to the transistor in the display area, forming a pixel defining layer on the pixel electrode in the display area and a preliminary upper layer of the dam in the non-display area, and forming the dam in the non-display area and a separation opening in the display area simultaneously by etching the preliminary lower layer and the pixel defining layer using an etching mask layer.

The etching mask layer may cover the preliminary lower layer and the preliminary upper layer of the dam.

A first thickness of the planarization layer in the display area may be substantially equal to a second thickness of a lower layer of the dam, and a third thickness of the pixel defining layer in the display area may be substantially equal to a fourth thickness of an upper layer of the dam.

A first width of the lower layer of the dame may be greater than a second width of the upper layer of the dam, and a sidewall of the lower layer of the dam may include two portions having different slopes.

The manufacturing method of a display device may further comprise forming a light emitting member and a common electrode on the pixel electrode in the display area, and a separation pattern separated from the common electrode in the separation opening.

The separation pattern may further include a portion separated from the light emitting member.

The forming the separation opening may include etching the pixel defining layer and a portion of the planarization layer.

The manufacturing method of a display device may further comprise forming an encapsulation layer on the common electrode using the dam as a mask supporter.

According to an embodiment, an electronic devices includes a display module, and a processor connected to the display module and controlling the display module. The display module may include a display device including a display area having a plurality of pixels and a non-display area surrounding the display area. The display device may comprise a transistor located on a first substrate in the display area, a pixel electrode connected to the transistor, a light emitting member on the pixel electrode, a common electrode on the light emitting member, a planarization layer having a substantially uniform thickness and located between the transistor and the pixel electrode in the display area, a pixel defining layer on the pixel electrode, and a dam located on the first substrate in the non-display area. The dam may include a lower layer including a same layer as the planarization layer and an upper layer including a same layer as the pixel defining layer, and the pixel defining layer may have a separation opening located between two adjacent pixels of the plurality of pixels.

According to embodiments, a display device, a manufacturing method of the display device, and an electronic device including the display device, that are capable of preventing lateral current leakage in a high-resolution display device and reducing manufacturing costs, are provided.

However, it is obvious that the effect of the embodiments is not limited to the above-described effect and may be variously extended without departing from the spirit and scope of the present disclosure.

### BRIEF DESCRIPTION OF THE DRAWINGS

FIG. 1 illustrates a schematic perspective view of a display device according to an embodiment.

FIG. 2 illustrates a cross-sectional view of a display device according to an embodiment.

FIG. 3 illustrates a schematic top plan view showing a display area of a display device according to an embodiment.

FIG. 4 illustrates a schematic cross-sectional view of a light emitting member of a display device according to an embodiment.

FIG. 5 to FIG. 10 illustrate schematic cross-sectional views showing a manufacturing method for a display device according to an embodiment.

FIG. 11 illustrates a cross-sectional view of a display device according to an embodiment.

FIG. 12 illustrates a schematic cross-sectional view showing a manufacturing method for a display device according to an embodiment.

FIG. 13 to FIG. 16 illustrate schematic top plan views showing a portion of a display device according to embodiments.

FIG. 17 illustrates a block diagram of an electronic device according to an embodiment.

FIG. 18 to FIG. 20 illustrate schematic diagrams of electronic devices according to embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways without departing from the spirit or scope of the present disclosure.

To clearly describe the present disclosure, parts that are irrelevant to the description are omitted, and like numerals refer to like or similar components throughout the specification.

The accompanying drawings are provided only in order to facilitate understanding of the embodiments in the present disclosure and are not to be interpreted as limiting the spirit or scope of the present disclosure. It should be understood that this disclosure includes all modifications, equivalents, and substitutions without departing from the scope and spirit of the present disclosure.

The size and thickness of each component shown in the accompanying drawings are arbitrarily given for better understanding and ease of description, so the present disclosure is not limited to the illustrated size and thickness. For example, in the drawings, the thickness of layers, films, panels, regions, etc., are exaggerated for clarity, better understanding and ease of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present between the element and another element. Further, in the specification, being “above” or “on” a reference part means being positioned above or below the reference part and does not necessarily mean being positioned “above” or “on” it in the opposite direction of gravity.

In addition, unless explicitly stated to the contrary, the word “include,” “comprise,” or “have” and its variations such as “including,” “comprising,” “having,” or etc. will be understood to imply the inclusion of stated elements but not the exclusion of any other elements.

Further, throughout the specification, the phrase “in a plan view” refers to viewing the target part from above, and the phrase “in a cross-sectional view” refers to viewing a vertical cut of the target part from the side.

In addition, throughout the specification, “connected” does not only mean that two or more components are directly connected, but may also mean that two or more components are connected indirectly through other components. It may also mean a physical connection, an electrical connection, or functionally or structurally integrated components that are referred by different names depending on their location or function.

Hereinafter, various embodiments and their variations will be described in detail with reference to the drawings.

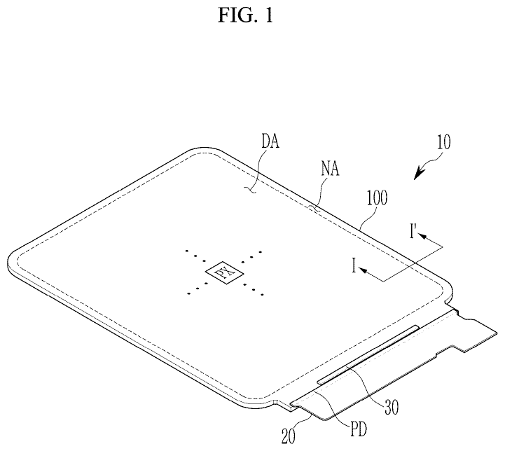

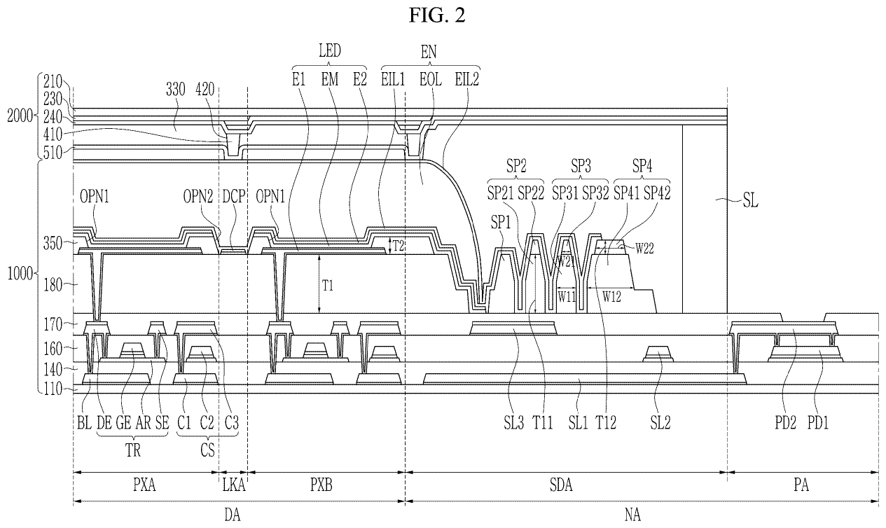

Referring to FIG. 1 and FIG. 2, a display device 10 according to an embodiment will be described. FIG. 1 illustrates a schematic perspective view of a display device according to an embodiment. FIG. 2 illustrates a cross-sectional view of a display device according to an embodiment.

Referring to FIG. 1, the display device may include a display panel 10, a flexible printed circuit film 20 bonded to the display panel 10, a driving unit including an integrated circuit chip 30, etc.

The display panel 10 may include a display area DA which displays an image and a non-display area NA in which circuits and/or signal lines for generating and/or transferring various signals and voltages applied to the display area DA are located. The non-display area NA may surround a periphery of the display area DA. In FIG. 1, the inside and outside of a dotted quadrangle may correspond to the display area DA and the non-display area NA, respectively.

The display area DA of the display panel 10 may include a plurality of pixels PX. In addition, the display area DA may include signal lines such as a gate line (also called a scan line), a data line, and a driving voltage line. The gate line, the data line, the driving voltage line, etc. are connected to each pixel PX, and each pixel PX may receive a gate signal (also referred to as a scan signal), a data voltage, and a driving voltage (also referred to as a first power voltage or a high-potential power voltage) from these signal lines. The pixels PX may include light emitting elements such as a light emitting diodes.

A touch sensor for detecting a user's touch may be located in an area corresponding to the display area DA. Although FIG. 1 illustrates the display area DA having a substantially quadrangular shape with a rounded edge, the display area DA may have various shapes such as a polygonal shape, a circular shape, an elliptical shape, and the like.

Although the display area DA is shown as flat, the embodiment of the present disclosure is not limited thereto, and the display area DA may include a curved portion.

A pad region PA, in which a pad portion PD for receiving signals from the outside of the display panel 10 are arranged, may be located in the non-display area NA. A pad region PA may be located on one edge of the display panel 10 and extend in a first direction x along one edge of the display panel 10. However, the embodiment may be limited thereto. The flexible printed circuit film 20 may be bonded to the pad portion PD and pads of the flexible printed circuit film 20 may be electrically connected to pad portion PD.

A driving unit may be located in the non-display area NA of the display panel 10 to generate and/or process various signals for driving the display panel 10. The driving unit may include a data driver for applying a data voltage to the data line, a gate driver for applying a gate signal to the gate line, and a signal controller for controlling the data driver and the gate driver. The pixels PX may receive the data voltage at a predetermined timing in response to the gate signal generated by the gate driver. However, the present disclosure is not limited thereto. For example, the gate driver may be integrated in the display panel 100, and may be located on at least one side of the display area DA or the non-display area NA. The data driver and the signal controller may be provided as an integrated circuit chip (also referred to as a driving IC chip) 30, and the integrated circuit chip 30 may be mounted in the non-display area NA of the display panel 10. The integrated circuit chip 30 may be mounted on the flexible printed circuit film 20 or the like to be electrically connected to the display panel 100.

Hereinafter, as a display device 10 according to an embodiment, an organic light emitting diode will be described as an example, but the display device 10 of the present disclosure is not limited thereto. For example, the display device 10 may be an inorganic light emitting display or an inorganic EL display device, or a display device such as a quantum dot light emitting display. For example, a light emitting layer of a display element provided in the display device 10 may include an organic material, an inorganic material, quantum dots, an organic material and quantum dots, or an inorganic material and quantum dots.

Referring to FIG. 2, the display panel 100 of the display device 10 may include a first panel 1000 and a second panel 2000. Although not shown, the display device 10 may further include a touch sensing portion, and the touch sensing portion may overlap the first panel 1000 and the second panel 2000. For example, the touch sensing portion may be located between the first panel 1000 and the second panel 2000 or on the second panel 2000.

The display area DA may include a first pixel area PXA and a second pixel area PXB adjacent to each other.

The non-display area NA may include an outer periphery region SDA in which a plurality of dams SP1, SP2, SP3, a support SP4, and a sealant SL are located, and a pad region PA in which pad layers PD1, PD2 for connecting to external driving circuits are located.

The first panel 1000 of the first pixel area PXA and the second pixel area PXB may include a transistor TR on a first substrate 110 and a light emitting element LED connected to the transistor TR, respectively.

The first substrate 110 may include a flexible material such as plastic, etc. that is easily bent, folded, or rolled. Although not shown, the first substrate 110 may include a plurality of insulating films overlapping each other, and may further include a barrier film located between the insulating films.

Although not shown, a buffer layer may be located on the first substrate 110.

A lower electrode layer BL and a first electrode C1 of a capacitor CS may be located on the first substrate 110 in the display area DA, and a first signal transmitting line SL1 may be located on first substrate 110 in the non-display area NA.

The lower electrode layer BL may overlap a semiconductor layer AR of the transistor TR and may prevent external light from being incident to the semiconductor layer AR. The lower electrode layer BL may be connected to the transistor TR.

A first insulating layer 140 may be located on the lower electrode layer BL, the first electrode C1 of the capacitor CS, and the first signal transmitting line SL1.

A semiconductor layer AR of the transistor TR, a gate insulating layer GL, gate electrode GE, and a second electrode C2 of the capacitor CS may be located on the first insulating layer 140 in the display area DA, and a second signal transmitting line SL2 and a first pad layer PD1 may be located on the first insulating layer 140 in the non-display area NA.

The semiconductor layer AR may include a first region, a second region, and a channel region between the first region and the second region. The semiconductor layer AR may include one of amorphous silicon, polycrystalline silicon, and oxide semiconductor. For example, the semiconductor layer AR may include low temperature polycrystalline silicon (LTPS), or oxide semiconductor including at least one of zinc (Zn), indium (In), gallium (Ga), or tin (Sn). For example, the semiconductor layer AR may include IGZO (Indium-Gallium-Zinc Oxide).

The gate insulating layer GL may be located between the semiconductor layer AR and the gate electrode GE, and may include an inorganic insulating material such as silicon nitride, silicon oxide, or silicon nitric oxide. The gate insulating layer GL may be a single layer or multi-layers.

A second insulating layer 160 may be located on the first insulating layer 140, the semiconductor layer AR, the gate insulating layer GL and the gate electrode GE, the second electrode C2 of the capacitor CS, and the second signal transmitting line SL2. The second insulating layer 160 may include an inorganic insulating material such as silicon nitride, silicon oxide, or silicon nitric oxide, and the gate insulating layer GL may be a single layer or multi-layers.

A first electrode SE and a second electrode DE of the transistor TR, and a third electrode C3 of the capacitor CS may be located on the second insulating layer 160 in the display area DA, and a third signal transmitting line SL3 and a second pad layer PD2 may be located on the second insulating layer 160 in the non-display area NA.

The first electrode SE and the second electrode DE may be connected to the first region and the second region of the semiconductor layer AR, respectively, through contact holes in the insulating layers 140, 160. One of the first electrode SE and the second electrode DE may be a source electrode and the other one of the first electrode SE and the second electrode DE may be a drain electrode.

The third electrode C3 of capacitor CS may be connected to the first electrode C1 of the capacitor CS through a contact hole in the insulating layers 140, 160.

The second pad layer PD2 may be connected to the first pad layer PD1 and the second signal transmitting line SL1 through contact holes in the insulating layers 140, 160.

A third insulating layer 170 may be located on the first electrode SE and the second electrode DE of the transistor TR, the third electrode C3 of the capacitor CS, the third signal transmitting line SL3 and the second pad layer PD2. A planarization layer 180 may be located on the third insulating layer 170. The planarization layer 180 may be an organic insulating layer. For example, the planarization layer 180 may include organic insulating materials such as general-purpose polymers including poly (methyl methacrylate) and polystyrene, polymer derivatives having phenolic groups, acrylic polymers, imide polymers (e.g., polyimide), and siloxane polymers.

A pixel electrode E1 may be located on the planarization layer 180 in the display area DA. The pixel electrode E1 may be electrically connected to the second electrode DE of the transistor TR through a contact hole in the planarization layer 180 and the third insulating layer 170 to receive a driving current for controlling the brightness of the light emitting element LED.

The transistor TR to which the pixel electrode E1 is connected may be a driving transistor or a transistor connected to the driving transistor. The pixel electrode E1 may include a reflective conductive material, a semi-transparent conductive material, or a transparent conductive material. The pixel electrode E1 may include a transparent conductive material such as indium tin oxide (ITO), and indium zinc oxide (IZO). The pixel electrode E1 may include a metal or metal alloy such as lithium (Li), calcium (Ca), aluminum (Al), silver (Ag), magnesium (Mg), or gold (Au). The pixel electrode E1 may be multi-layers. For example, the pixel electrode E1 may have a triple-layered structure such as ITO/silver/ITO.

A pixel defining layer 350 may be located on the planarization layer 180. The pixel defining layer 350 may be an organic insulating layer. The pixel defining layer 350 may have a pixel opening OPN1 extending to at least portion of the pixel electrode E1. The pixel opening OPN1 of the pixel defining layer 350 may define a light emitting region of the display device. The pixel defining layer 350 may have a separation opening OPN2 located in a separation region LKA between adjacent pixel areas PXA and PXB and surrounding the separation pattern DCP.

A light emitting member EM of the light emitting element LED may be located on the pixel electrode E1. The light emitting member EM may include a common layer that is interconnected between adjacent pixels and located commonly in the adjacent pixels.

A common electrode E2 of the light emitting element LED may be located on the light emitting member EM. The common electrode E2 may include a low work function metal such as calcium (Ca), barium (Ba), magnesium (Mg), aluminum (Al), silver (Ag), or a metal alloy. The common electrode E2 may be a thin layer to have light transmittance. The common electrode E2 may include a transparent conductive oxide such as indium tin oxide (ITO) or indium zinc oxide (IZO). A common voltage may be applied to the common electrode E2.

The pixel electrode E1, the light emitting member EM, and the common electrode E2 of each pixel PX may form a light emitting element LED such as an organic light emitting diode or an inorganic light emitting diode. The pixel electrode E1 may be an anode of the light emitting element LED, and the common electrode E2 may be a cathode of the light emitting element LED.

A separation pattern DCP may be located in the separation opening OPN2 of the pixel defining layer 350 between adjacent pixel areas PXA and PXB.

The separation pattern DCP may include the same layers as the light emitting member EM and the common electrode E2.

Portions of the light emitting member EM and the common electrode E2 may be discontinuously formed due to a step-difference of the separation opening OPN2 in the pixel defining layer 350 and may form the separation pattern DCP. That is, the separation pattern DCP is separated from the light emitting member EM and the common electrode E2. In this way, the common layer of the adjacent pixel areas PXA and PXB, such as the common layer of the light emitting member EM and the common electrode E2, may be separated in a non-light emitting area between the adjacent pixel areas PXA and PXB to form the separation pattern DCP, so the lateral leakage current in the high-resolution structure may be prevented.

The planarization layer 180 in the display area DA may have no step-difference, so the pixel defining layer 350 may cover a sidewall of the pixel electrode E1 without increasing the thickness of the pixel defining layer 350.

An encapsulation layer EN may be located on the common electrode E2. The encapsulation layer EN may encapsulate a light emitting element LED to prevent moisture or oxygen from penetrating from the outside. The encapsulation layer EN may be a thin-film encapsulation layer including one or more inorganic layers EIL1 and EIL2 and one or more organic layers EOL.

A touch sensor layer (not illustrated) including touch electrodes may be located on the encapsulation layer EN. The touch electrodes may have a mesh shape having an opening corresponding to the light emitting element LED. An anti-reflection layer (not illustrated) for reducing external light reflection may be located on the touch sensor layer.

A capping layer (not illustrated) may be located on the common electrode E2. The capping layer may increase light efficiency by adjusting a refractive index. The capping layer may be located to entirely cover the common electrode E2. The capping layer may include an organic insulating material, or may include an inorganic insulating material.

The second panel 2000 may be located on the encapsulation layer EN.

The second panel 2000 may include a second substrate 210 opposite to the first substrate 110 of the first panel 1000, a plurality of color filters 230, a third insulating layer 240, a partition wall 410, a plurality of color converting layers 330, and fourth insulating layer 510.

The second substrate 210 may include a flexible material, such as plastic, that is easily bent, folded, or rolled.

The second panel 2000 may include an overlapping region of the color filters 230 for transmitting light of different colors to serve a light blocking region, without an additional light blocking member.

The partition wall 410 may overlap the pixel defining layer 350 of the first panel 1000. That is, the partition wall 410 overlaps an opaque region of the first panel 1000, and the color converting layers 330 is located in an area between adjacent partition walls 410 to overlap a light emitting region of the first panel 1000.

The partition wall 410 overlaps a light blocking region (for example, an overlapping region of the color filters 230) of the second panel 2000.

The partition wall 410 may have openings 420 overlapping the color filters 230, and the color converting layers 330 may be disposed in the openings 420 of the partition wall 410. That is, the color converting layers 330 may be disposed in a region surrounded by the partition wall 410.

The color converting layers 330 may include a transmission layer (not shown) transmitting light with a first wavelength that is incident from the light emitting element LED of the first display panel 1000 and including a plurality of scatterers (not shown), a first color converting layer converting the light with a first wavelength incident from the light emitting element LED of the first display panel 1000 into light with a second wavelength and including a plurality of first quantum dots and a plurality of scatterers, and a second color converting layer converting the light with a first wavelength incident from the light emitting element LED of the first display panel 1000 into light with a third wavelength and including a plurality of second quantum dots and a plurality of scatterers. The light with a first wavelength may be blue light with a peak wavelength of about 380 nm to about 480 nm, for example, equal to or greater than about 420 nm, equal to or greater than about 430 nm, equal to or greater than about 440 nm, or equal to or greater than about 445 nm, and equal to or less than about 470 nm, equal to or less than about 460 nm, or equal to or less than about 455 nm. The light with a second wavelength may be red light with a peak wavelength of about 600 nm to about 650 nm, for example, about 620 nm to about 650 nm, and the light with a third wavelength may be green light with a peak wavelength of about 500 nm to about 550 nm, for example, about 510 nm to about 550 nm.

The color filters 230 may include a first color filter for transmitting the light with a second wavelength and absorbing the light with other wavelengths to increase the purity of the light with a second wavelength color-converted after passing through the first color converting layer and emitted toward the second substrate 210, a second color filter for transmitting the light with a third wavelength and absorbing the light with other wavelengths to increase the purity of the light with a third wavelength color-converted after passing through the second color converting layer and emitted toward the second substrate 210, and a third color filter for transmitting the light with a first wavelength having passed through the transmission layer and absorbing the light with other wavelengths to increase the purity of the light with a first wavelength having passed through the transmission layer and emitted toward the second substrate 210.

The scatters may scatter the light input to the color converting layers 330 to increase efficiency of light.

The fourth insulating layer 510 may cover and protect the color converting layers 330 to prevent a component of a filling layer injected when the second panel 2000 is attached to the first panel 1000 from being input to the color converting layers 330.

A plurality of dams SP1, SP2, SP3, and a support SP4 may be located on the third insulating layer 170 in the non-display area NA.

The first dam SP1, the second dam SP2, the third dam SP3, and the support SP4 may be located in order away from the display area DA. That is, the second dam SP2 is located on the outer side than the first dam SP1, the third dam SP3 is located on the outer side than the second dam SP2, and the support SP4 is located on the outer side than the third dam SP3.

The inorganic layers EIL1, EIL2 of the encapsulation layer EN, which are formed on the front side of the first substrate 110, are located on the first dam SP1, the second dam SP2, and the third dam SP3, and the organic layer EOL of the encapsulation layer EN may not be located on the plurality of dams SP1, SP2, SP3 in the non-display area NA.

The plurality of dams SP1, SP2, SP3 may prevent an organic material from overflowing to a region in which the sealant SL is located.

The first dam SP1 may include a same layer as the planarization layer 180. The second dam SP2, the third dam SP3, and the support SP4 may include lower layers SP21, SP31, SP41 including the same layer as the planarization layer 180 and upper layer SP22, SP32, SP42 including the same layer as the pixel defining layer 350. In this disclosure, including the same layer may mean including the same material and being formed by the same process.

The support SP4 may support a mask which is used in a process for forming the inorganic layers EIL1, EIL2 of the encapsulation layer EN.

Widths W11, W12 of the lower layer SP21, SP31, SP41 of the second dam SP2, the third dam SP3, and the support SP4 may be greater than widths W21, W22 of the upper layer SP22, SP32, SP42 of the second dam SP2, the third dam SP3, and the support SP4.

Sidewalls of the lower layer SP21, SP31, SP41 of the second dam SP2, the third dam SP3, and the support SP4 may include portions having different slopes.

A thickness T11 of the lower layer SP21, SP31, SP41 may be substantially equal to a thickness T1 of the planarization layer 180 in the display area DA, and a thickness T12 of the upper layer SP22, SP32, SP42 may be substantially equal to a thickness T2 of the pixel defining layer 350 in the display area DA.

Each pixel PX of the display panel 100 shown in FIG. 2 is only one example, and the embodiment may not be limited thereto. Though one transistor TR is shown in FIG. 2, the embodiment may not be limited thereto, and each pixel PX may include a plurality of transistors.

The sealant SL may be located in the outer side of the plurality of dams SP1, SP2, SP3 and the support SP4 in the non-display area NA, and the sealant SL may be located between the first panel 1000 and the second panel 2000 to connect the first panel 1000 and the second panel 2000 to each other.

A filling layer (not shown) may be located in a region surrounded by the sealant SL between the first panel 1000 and the second panel 2000.

The planarization layer 180 may be removed in the pad region PA to prevent moisture, etc. from flowing into the display area DA through the pad area PA connected to the flexible printed circuit film 20.

In addition, the planarization layer 180 between the support SP4 and the plurality of dams SP1, SP2, SP3 and the planarization layer 180 under the sealant SL may be removed to prevent moisture, etc. from flowing into the display area DA through a region under the sealant SL.

In addition, the pixel defining layer 350 may have the separation opening OPN2 located in a region between the adjacent pixel areas PXA and PXB, and the common layer of the light emitting member EM and the common electrode E2 may be separated in a non-light emitting area between the adjacent pixel areas PXA and PXB to form the separation pattern DCP, so the lateral leakage current in the high-resolution structure may be prevented.

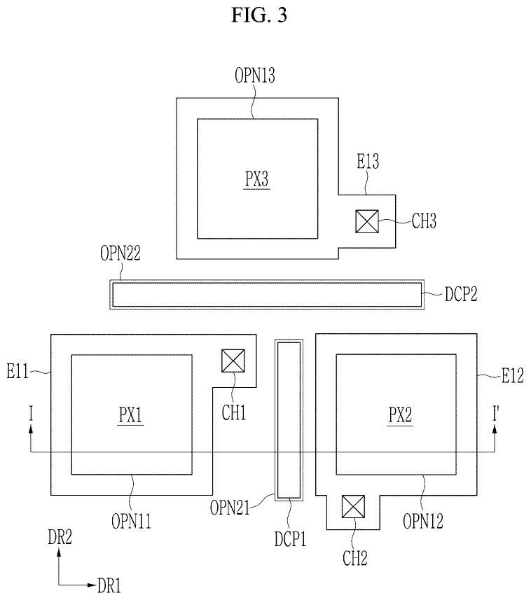

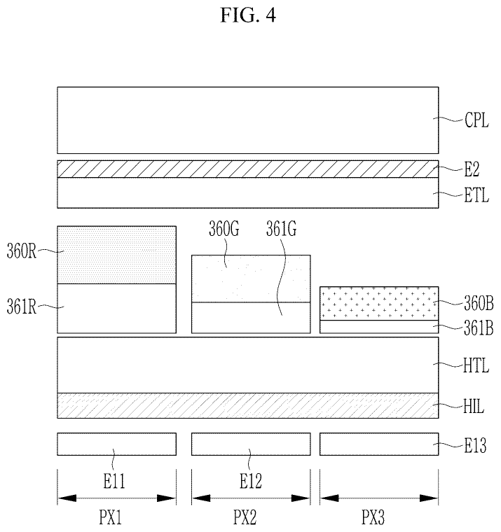

Referring to FIG. 3 and FIG. 4, the separation opening OPN2 and the separation pattern DCP will be described. FIG. 3 illustrates a schematic top plan view showing a display area of a display device according to an embodiment. FIG. 4 illustrates a schematic cross-sectional view of a light emitting member of a display device according to an embodiment.

Referring to FIG. 3, the display area DA of the display device according to an embodiment may include a first pixel PX1, a second pixel PX2, and a third pixel PX3. Each of the first pixel PX1, the second pixel PX2, and the third pixel PX3 may include at least one transistor TR and a light emitting element LED connected to the transistor TR.

According to an embodiment, the first pixel PX1 may emit red light, the second pixel PX2 may emit green light, and the third pixel PX3 may emit blue light, but the embodiment is not limited thereto. The display device may include light emitting areas that emit red light, green light, and blue light, and a non-light emitting area other than the light emitting area.

According to an embodiment, the first pixel PX1, the second pixel PX2, and the third pixel PX3 may have different sizes from each other.

According to an embodiment, each of the first pixel PX1, the second pixel PX2, and the third pixel PX3 is shown in a quadrangular shape. However, the present disclosure is not limited thereto, and each of the first pixel PX1, the second pixel PX2, and the third pixel PX3 may be modified to have various shapes. In addition, each of the first pixel PX1, the second pixel PX2, and the third pixel PX3 is shown in a quadrangular shape with different sizes. However, the present disclosure is not limited thereto, and each of the first pixel PX1, the second pixel PX2, and the third pixel PX3 may be modified to have various sizes. According to an embodiment, the arrangement of pixels in which the first pixel PX1 and the second pixel PX2 are adjacent to each other along the first direction DR1, the first pixel PX1 and the third pixel PX3 are adjacent to each other along the second direction DR2, and the second pixel PX2 and the third pixel PX3 are adjacent to each other along the second direction DR2. However, the present disclosure is not limited thereto, and the first pixel PX1, the second pixel PX2, and the third pixel PX3 may be arranged in various forms.

According to an embodiment, the display area DA may include a plurality of separation patterns DCP1, DCP2.

The plurality of separation patterns DCP1, DCP2 may include a first separation pattern DCP1 between the first pixel PX1 and the second pixel PX2, and a second separation DCP2 between the third pixel PX3 and the first and second pixels PX1 and PX2.

A pixel electrode E11 of the first pixel PX1 may be connected to a transistor (not shown) through a contact hole CH1, a pixel electrode E12 of the second pixel PX2 may be connected to a transistor (not shown) through a contact hole CH2, and a pixel electrode E13 of the third pixel PX3 may be connected to a transistor (not shown) through a contact hole CH3.

The pixel defining layer 350 may have a first pixel opening OPN11 extending to the pixel electrode E11 of the first pixel PX1, a second pixel opening OPN12 extending to the pixel electrode E12 of the second pixel PX2, and a third pixel opening OPN13 extending to the pixel electrode E13 of the third pixel.

In addition, the pixel defining layer 350 may have a first separation opening OPN21 surrounding the first separation pattern DCP1 and a second separation opening OPN22 surrounding the second separation pattern DCP2.

Referring to FIG. 2 and FIG. 3, a common layer of the light emitting members EM and the common electrode E2 of the first pixel PX1, the second pixel PX2, and the third pixel PX3 may be separated from each other in the first separation opening OPN21 and the second separation opening OPN22. The separated common layer of the light emitting member EM and the common electrode E2 may form the first separation pattern DCP1 in the first separation opening OPN21 and the second separation pattern DCP2 in the second separation opening OPN22.

According to an embodiment, when a plane formed by an intersection of the first direction DR1 and the second direction DR2 is viewed from above, the first separation pattern DCP1 and the second separation pattern DCP2 of the common layer of the light emitting member EM and the common electrode E2 may have substantially the same planar shape as the first separation opening OPN21 and the second separation opening OPN22, but the embodiment is not limited thereto.

According to an embodiment, the common layer of the light emitting members EM and the common electrode E2 of the first pixel PX1, the second pixel PX2, and the third pixel PX3 may be separated in the first separation opening OPN21 and the second separation opening OPN22, so the lateral leakage current in the high-resolution structure may be prevented.

Referring to FIG. 4, a structure of the light emitting element LED of the pixels and the lateral leakage current of the plurality of pixels will be described in more detail. In FIG. 4, a configuration common to each of the pixels PX1, PX2, and PX3 is shown as a single unit.

Referring to FIG. 4, a hole injection layer HIL and a hole transport layer HTL are located on the first electrodes E11, E12, and E13 of each of the pixels PX1, PX2, and PX3. The hole injection layer HIL is commonly located in each of the pixels PX1, PX2, and PX3. The hole transport layer HTL is also commonly located in each of the pixels PX1, PX2, and PX3. The common layer of the light emitting member EM having the first separation opening OPN21 and the second separation opening OPN22 described above may include at least one of the hole injection layer HIL and the hole transport layer HTL that are commonly located in each of the pixels PX1, PX2, and PX3.

The first pixel PX1 may include a first auxiliary layer 361R and a first light emitting layer 360R. The second pixel PX2 may also include a second auxiliary layer 361G and a second light emitting layer 360G. The third pixel PX3 may also include a third auxiliary layer 361B and a third light emitting layer 360B.

An electron transport layer ETL may be positioned on each of the first light emitting layer 360R, the second light emitting layer 360G, and the third light emitting layer 360B. The electron transport layer ETL is commonly positioned in each of the pixels PX1, PX2, and PX3.

The common electrode E2 may be positioned on the electron transport layer ETL. The common electrode E2 may be commonly positioned in each of the pixels PX1, PX2, and PX3.

Each of the pixels PX1, PX2, and PX3 may include a common hole injection layer HIL to improve a hole injection characteristic. In this case, the hole injection layer HIL may be a doped hole transport layer HTL. That is, the hole injection layer HIL, which is a doped layer, may have higher electrical conductivity than that of the hole transport layer. Accordingly, a side leakage current problem may occur due to conductive characteristics.

When leakage current occurs, pixel efficiency decreases and color purity deteriorates, and the leakage current may cause adjacent pixels to weakly light up and cause color mixing. In particular, since a distance between adjacent pixels is narrow in high-resolution displays, such a leakage current problem may appear more significant.

According to an embodiment, the common layer of the light emitting members EM and the common electrode E2 in the non-light emitting areas between adjacent pixels may be separated from each other in the first separation opening OPN21 and the second separation opening OPN22, and the separated common layer of the light emitting member EM and the common electrode E2 may form the first separation pattern DCP1 in the first separation opening OPN21 and the second separation pattern DCP2 in the second separation opening OPN22.

Accordingly, the leakage current may be reduced by short-circuiting the common layer of the light emitting member EM and the common electrode E2 between adjacent pixels. In addition, regions of the first separation pattern DCP1 and the second separation pattern DCP2 may correspond to portions of the non-light emitting areas between adjacent pixels, leading to the prevention of a voltage drop of the common voltage applied to the common electrode E2 caused by the first separation pattern DCP1 and the second separation pattern DCP2 and enabling a stable driving a high-resolution display device.

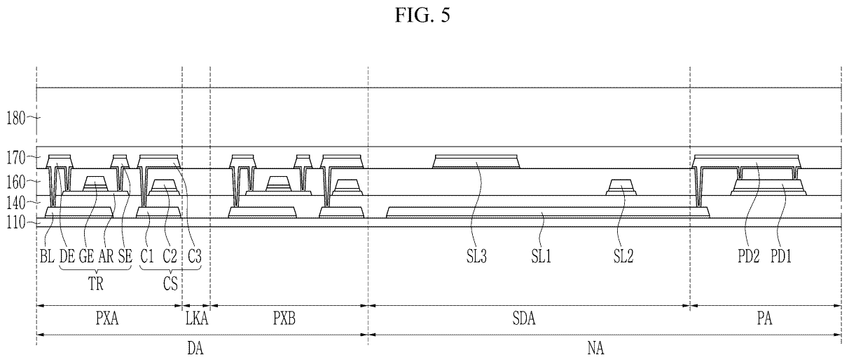

Referring to FIG. 5 to FIG. 10 with FIG. 1 and FIG. 2, a manufacturing method of a display device according to an embodiment will be described. FIG. 5 to FIG. 10 illustrate schematic cross-sectional views showing a manufacturing method of a display device according to an embodiment.

Referring to FIG. 5 with FIG. 1 and FIG. 2, the lower electrode layer BL, the transistor TR, and the capacitor CS may be formed on the first substrate 110 in the display area DA, the signal transmitting lines SL1, SL2, SL3 may be formed on the first substrate 110 in the outer periphery region SDA of the non-display area NA, the pad layers PD1, PD2 may be formed on the first substrate 110 in the pad region PA, the plurality of insulating layers 140, 160, 170 may be formed, and the planarization layer 180 may be deposited thereon.

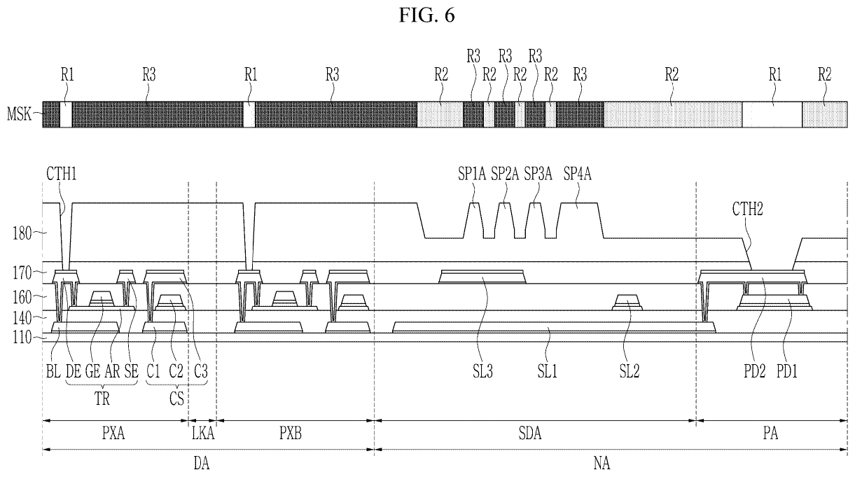

Referring to FIG. 6, a photoresist may be deposited on the planarization layer 180, photoetching may be performed using a photomask MSK having a first region R1, a second region R2, and a third region R3, each of which has a different light transmittance from one another.

Through the photoetching, a contact hole CTH1 exposing the second electrode DE may be formed in the third insulating layer 170 and the planarization layer 180, a portion of the planarization layer 180 in outer periphery region SDA may be removed to form preliminary dam portions SP1A, SP2A, SP3A, which become portions of the plurality of dams SP1, SP2, SP3, and a preliminary support SP4A, which become a portion of the support SP4, and a contact hole CTH2 exposing the second pad layer PD2 may be formed in the pad region PA, simultaneously.

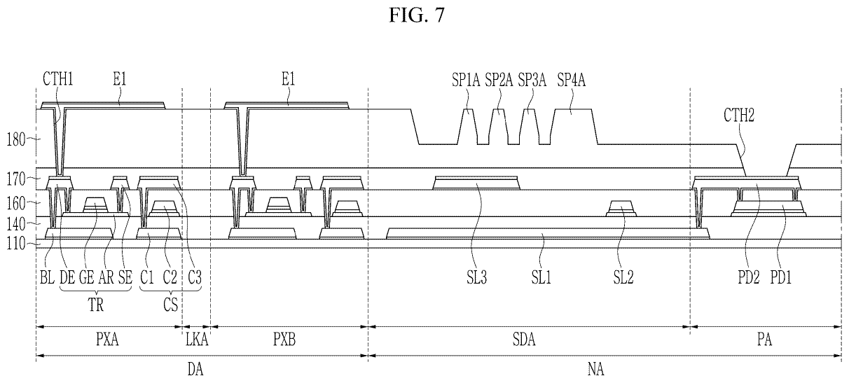

Referring to FIG. 7, the pixel electrode E1 which is connected to the second electrode DE through the contact hole CTH1 may be formed on the planarization layer 180 in the display area DA.

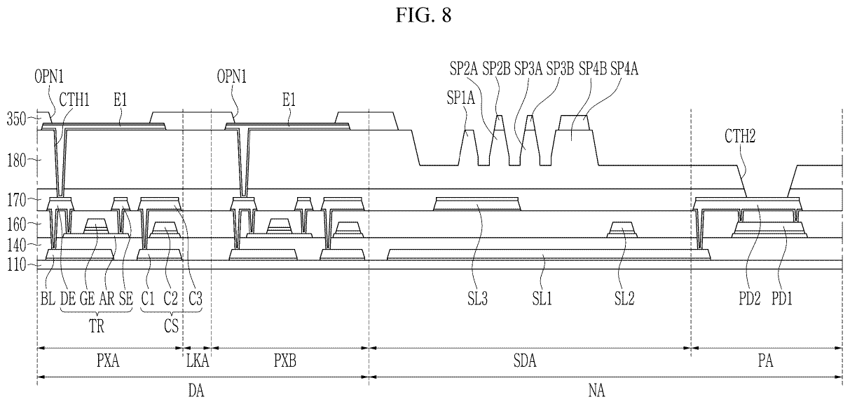

Referring to FIG. 8, the pixel defining layer 350 having the pixel opening OPN1 exposing the pixel electrode E1 may be formed on the pixel electrode E1 in the display area DA, and upper preliminary dam portions SP2B, SP3B, which become portions of the dams SP2, SP3, and an upper preliminary support SP4B, which become a portion of the support SP4, may be formed in the outer periphery region SDA.

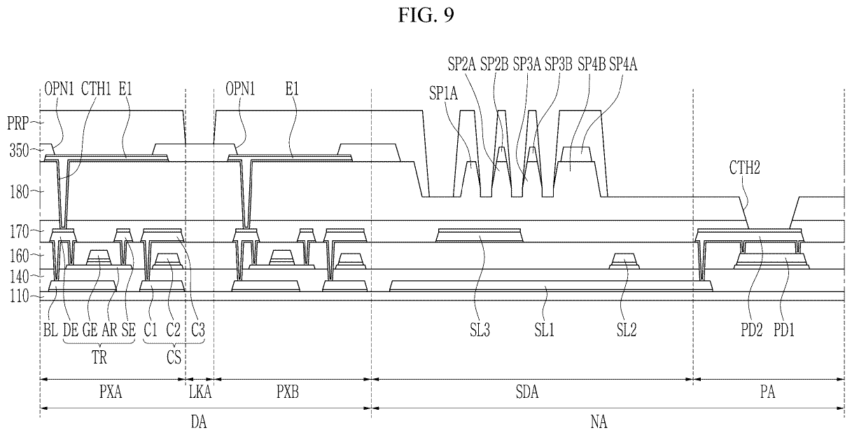

Referring to FIG. 9, a photoresist layer may be deposited and a photolithography process may be performed to form etching mask layers PRP.

The etching mask layer PRP located in the display area DA may cover most of the pixel defining layer 350. However, the etching mask layer PRP may not cover the pixel defining layer 350 in an area correspond to the separation region LKA.

The etching mask layer PRP located in the non-display area NA may only be located in regions in which the plurality of dams SP1, SP2, SP3 and the support SP4 will be formed.

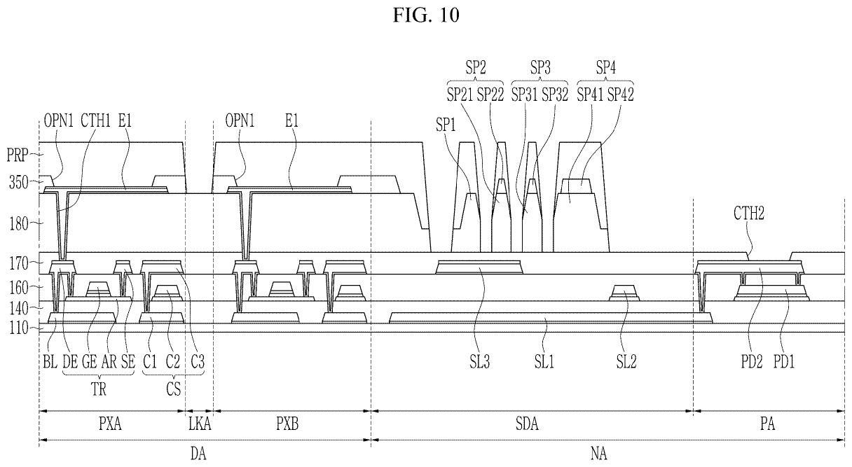

Referring to FIG. 10, the separation opening OPN2 may be formed in the separation region LKA of the display area DA by etching the pixel defining layer 350 using the etching mask layer PRP as an etching mask. Simultaneously, the plurality of dams SP1, SP2, SP3 and the support SP4 may be formed in the non-display area NA by etching the planarization layer 180 located in areas other than the regions in which the plurality of dams SP1, SP2, SP3 and the support SP4 will be formed, using the etching mask layer PRP as an etching mask. In the non-display area NA, the planarization layer 180 may be entirely removed in areas other than the regions in which the plurality of dams SP1, SP2, SP3 and the support SP4 are located.

Here, as the preliminary dam portions SP1A, SP2A, SP3A, the preliminary support SP4A, the upper preliminary dam portions SP2B, SP3B, and the upper preliminary support SP4B may be covered and protected by the etching mask layer PRP located in the regions in which the plurality of dams SP1, SP2, SP3 and the support SP4 will be formed, the heights of the plurality of dams SP1, SP2, SP3 and the support SP4 may not be unnecessarily lowered during the etching process. Accordingly, the thickness T11 of the lower layer SP21, SP31, SP41 may be substantially equal to a thickness T1 of the planarization layer 180 in the display area DA, and a thickness T12 of the upper layer SP22, SP32, SP42 may be substantially equal to a thickness T2 of the pixel defining layer 350 in the display area DA. In addition, as the widths W11, W12 of the lower layer SP21, SP31, SP41 of the second dam SP2, the third dam SP3, and the support SP4 may be greater than the widths W21, W22 of the upper layer SP22, SP32, SP42 of the second dam SP2, the third dam SP3, and the support SP4, the plurality of dams SP1, SP2, SP3 and the support SP4 may be stably maintained. In addition, by etching the planarization layer 180, after the preliminary dam portions SP1A, SP2A, SP3A, the preliminary support SP4A, the upper preliminary dam portions SP2B, SP3B, and the upper preliminary support SP4B are covered and protected by the etching mask layer PRP, to form the dams SP1, SP2, SP3 and the support SP4, the sidewalls of the lower layer SP21, SP31, SP41 that are etched twice may have portions having different slopes.

Then, after removing the etching mask layer PRP, the light emitting member EM and the common electrode E2 may be deposited to form the light emitting element LED and the separation pattern DCP, the encapsulation layer EN may be formed, and the sealant SL may be formed to connect the first panel 1000 and the second panel 2000 to each other, thereby forming the display device shown in FIG. 2.

According to the manufacturing method of the display device according to an embodiment, by forming the separation opening OPN2 in the separation area LKA of the display area DA and the plurality of dams SP1, SP2, SP3 and the support SP4 in the non-display area NA using a single etching mask layer PRP, the manufacturing cost may be reduced. In addition, as the preliminary dam portions SP1A, SP2A, SP3A, the preliminary support SP4A, the upper preliminary dam portions SP2B, SP3B, and the upper preliminary support SP4B may be covered and protected by the etching mask layer PRP, the heights of the plurality of dams SP1, SP2, SP3 and the support SP4 may not be unnecessarily lowered during the etching process. As the widths W11, W12 of the lower layer SP21, SP31, SP41 of the second dam SP2, the third dam SP3, and the support SP4 may be greater than the widths W21, W22 of the upper layer SP22, SP32, SP42 of the second dam SP2, the third dam SP3, and the support SP4, the plurality of dams SP1, SP2, SP3 and the support SP4 may be stably maintained. In addition, as the pixel defining layer 350 may have the separation opening OPN2 located in the region between adjacent pixels PXA and PXB, and the common layer of the light emitting member EM and the common electrode E2 may be separated in the separation opening OPN2 to form the separation pattern DCP, the lateral leakage current in the high-resolution structure may be prevented.

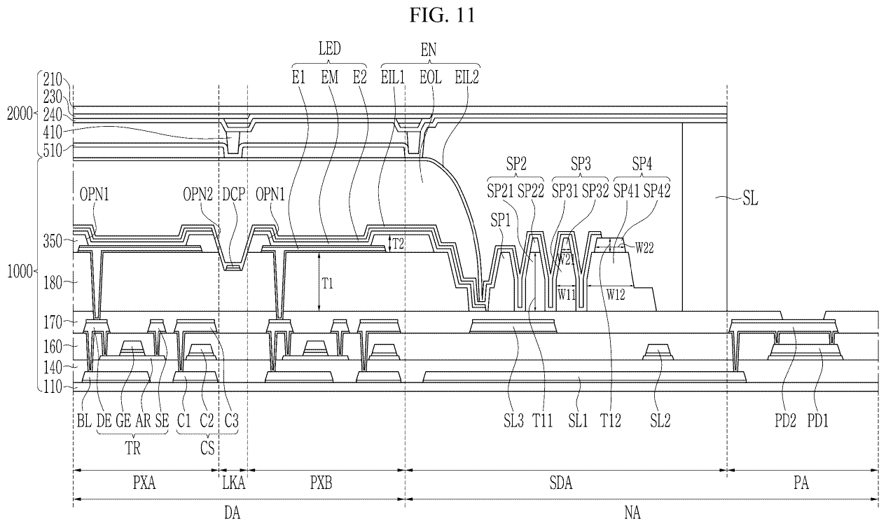

Referring to FIG. 11, a display device according to an embodiment will be described. FIG. 11 illustrates a cross-sectional view of a display device according to another embodiment.

Referring to FIG. 11, the display device according to an embodiment is similar to the display device according to the embodiment described above with reference to FIG. 2. Specific descriptions of the same components are omitted.

The display device according to an embodiment may include the first panel 1000 and the second panel 2000. The first panel 1000 may include the lower electrode layer BL, the transistor TR, the capacitor CS, the light emitting element LED, and the separation pattern DCP located in the display area DA, the signal transmitting lines SL1, SL2, SL3 and the sealant SL located in the outer periphery region SDA of the non-display area NA, the pad layers PD1, PD2 located in the pad region PA of the non-display area NA, the plurality of insulating layers 140, 160, 170 located between layers, the planarization layer 180, the pixel defining layer 350, and the encapsulation layer EN. The second panel 2000 may include the plurality of color filter 230, the partition wall 410, and the plurality of color converting layers 330.

The separation opening OPN2 in the display device according to an embodiment may be formed not only in the pixel definition layer 350 but also in a portion of the planarization layer 180. Accordingly, the depth of the separation opening OPN2 may be relatively deep, and the common layer of the light emitting element EM and the common electrode E2 may be easily separated within the separation opening OPN2.

Many features of the display device according to the previously described embodiment shown in FIG. 2 are applicable to the display device according to an embodiment.

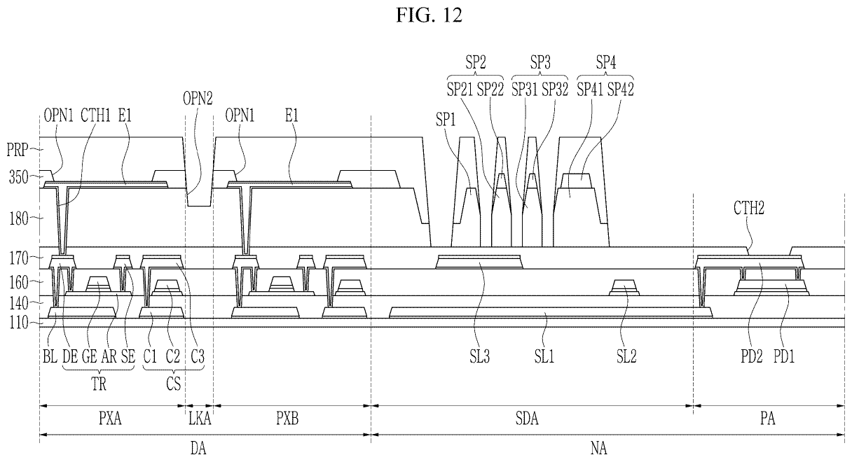

Referring to FIG. 12 with FIG. 5 to FIG. 11 and FIG. 11, a manufacturing method of a display device according to an embodiment will be described. FIG. 12 illustrates a schematic cross-sectional view showing a manufacturing method of a display device according to an embodiment.

As shown in FIG. 5 to FIG. 9, portions of the first panel 1000 may be formed and the etching mask layer PRP may be formed. Specific descriptions of the manufacturing method shown in FIG. 5 to FIG. 9 are omitted.

Referring to FIG. 12, the separation opening OPN2 may be formed in the separation region LKA of the display area DA by etching the pixel defining layer 350 and the portion of the planarization layer 180 using the etching mask layer PRP as an etching mask. Simultaneously, the plurality of dams SP1, SP2, SP3 and the support SP4 may be formed in the non-display area NA by etching the planarization layer 180 located in areas other than the regions in which the plurality of dams SP1, SP2, SP3 and the support SP4 will be formed, using the etching mask layer PRP as an etching mask. In the non-display area NA, the planarization layer 180 may be entirely removed in areas other than the regions in which the plurality of dams SP1, SP2, SP3 and the support SP4 are located.

According to the manufacturing method of the display device, when the separation opening OPN2 is formed, not only the pixel definition layer 350 but also the portion of the planarization layer 180 may be removed using the etching mask layer PRP as the etching mask.

According to the manufacturing method of the display device, as the separation opening OPN2 may be formed not only in the pixel definition layer 350 but also in the portion of the planarization layer 180, the depth of the separation opening OPN2 may be relatively deep, and the common layer of the light emitting element EM and the common electrode E2 may be easily separated within the separation opening OPN2.

Then, after removing the etching mask layer PRP, the light emitting member EM and the common electrode E2 may be deposited to form the light emitting element LED and the separation pattern DCP, the encapsulation layer EN may be formed, and the sealant SL may be formed to connect the first panel 1000 and the second panel 2000 to each other, thereby forming the display device shown in FIG. 11.

According to the manufacturing method of the display device according to an embodiment, by forming the separation opening OPN2 in the separation area LKA of the display area DA and the plurality of dams SP1, SP2, SP3 and the support SP4 in the non-display area NA using a single etching mask layer PRP, the manufacturing cost may be reduced. In addition, as the preliminary dam portions SP1A, SP2A, SP3A, the preliminary support SP4A, the upper preliminary dam portions SP2B, SP3B, and the upper preliminary support SP4B may be covered and protected by the etching mask layer PRP, the heights of the plurality of dams SP1, SP2, SP3 and the support SP4 may not be unnecessarily lowered during the etching process. As the widths W11, W12 of the lower layer SP21, SP31, SP41 of the second dam SP2, the third dam SP3, and the support SP4 may be greater than the widths W21, W22 of the upper layer SP22, SP32, SP42 of the second dam SP2, the third dam SP3, and the support SP4, the plurality of dams SP1, SP2, SP3 and the support SP4 may be stably maintained. In addition, as the pixel defining layer 350 may have the separation opening OPN2 located in the region between adjacent pixel areas PXA and PXB, and the common layer of the light emitting member EM and the common electrode E2 may be separated in the separation opening OPN2 to form the separation pattern DCP, the lateral leakage current in the high-resolution structure may be prevented.

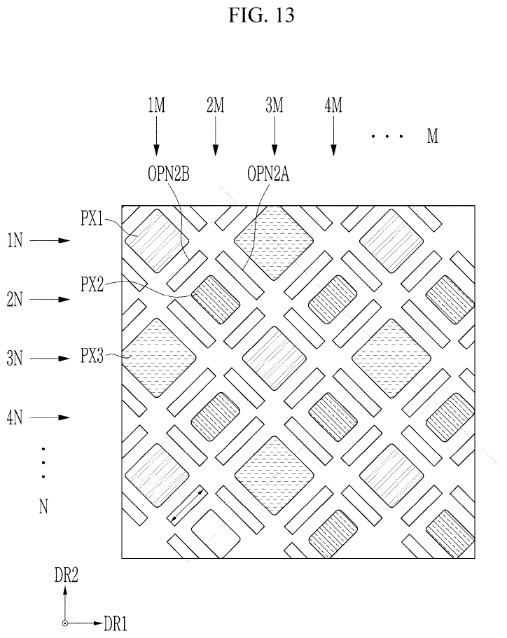

With reference to FIGS. 13 to 16, various examples of arrangement of pixels, separation patterns, light emitting members, and openings of common electrodes of display devices according to embodiments will be described. FIG. 13 to FIG. 16 illustrate a schematic top plan view showing a portion of a display device according to embodiments.

Referring to FIG. 13, a plurality of first pixels PX1 and third pixels PX3 may be arranged alternately in a first row 1N, a plurality of second pixels PX2 may be arranged at predetermined intervals in an adjacent second row 2N, a plurality of third pixels PX3 and first pixels PX1 may be alternately arranged in an adjacent third row 3N, a plurality of second pixels PX2 may be arranged at predetermined intervals in an adjacent fourth row 4N, and arrangement of these pixels PX1, PX2, and PX3 may be repeated up to the Nth row.

A plurality of first pixels PX1 and a plurality of third pixels PX3 arranged in the first row 1N and the plurality of second pixels PX2 arranged in the second row 2N may be alternately arranged. Accordingly, the first pixels PX1 and third pixels PX3 may be arranged alternately in a first column 1M, the second pixels PX2 may be arranged at predetermined intervals in an adjacent second column 2M, the third pixels PX3 and first pixels PX1 may be alternately arranged in an adjacent third column 3M, the second pixels PX2 may be arranged at predetermined intervals in an adjacent fourth column 4M, and the arrangement of these pixels PX1, PX2, and PX3 may be repeated up to an M^{th} column.

The separation opening OPN2A may be located between the second pixel PX2 and the third pixel PX3 to correspond to each side of a light emitting area of the third pixel PX3, so as to surround the light emitting area of one third pixel PX3. The separation opening OPN2B may be located between the first pixel PX1 and the second pixel PX2 to correspond to each side of the first pixel PX1.

Although not shown, separation patterns may be located in the separation openings OPN2A, OPN2B.

The light emitting member EM and the common electrode E2 between adjacent pixels may be short-circuited by the separation openings OPN2A and OPN2B, thereby reducing leakage current and stably driving a high-resolution display device.

Many features of the display device and the manufacturing method of the display device according to the previously described embodiments are applicable to the display device according to an embodiment shown in FIG. 13.

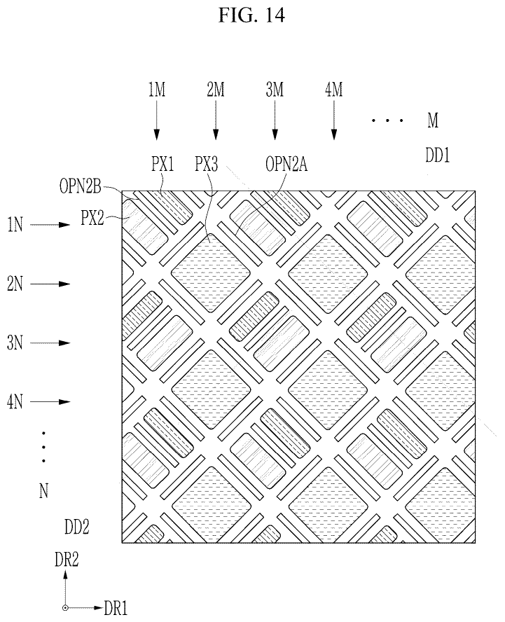

Referring to FIG. 14, the first pixels PX1 and the second pixels PX2 may be alternately arranged in a first row 1N, the third pixels PX3 may be arranged at predetermined intervals in an adjacent second row 2N, the second pixels PX2 and the first pixels PX1 may be alternately arranged in an adjacent third row 3N, the third pixels PX3 may be arranged at predetermined intervals in an adjacent fourth row 4N, and this arrangement of pixels may be repeated up to the N^{th} row.

The first pixels PX1 and the second pixels PX2 arranged in the first row 1N may be spaced apart in the first diagonal direction R1 and may be arranged parallel to the second diagonal direction R2, and the second pixels PX2 and the first pixels PX1 arranged in the third row 3N are spaced apart in the second diagonal direction R2 and may be arranged parallel to the first diagonal direction R1. Accordingly, a pair of first pixels PX1 and second pixels PX2 arranged parallel to the second diagonal direction R2 and a pair of first pixels PX1 and second pixels PX2 arranged parallel to the first diagonal direction R1 may be alternately arranged in a first column 1M, the third pixels PX3 may be arranged at predetermined intervals in an adjacent second column 2M, a pair of first pixels PX1 and second pixels PX2 arranged parallel to the second diagonal direction R2 and a pair of first pixels PX1 and second pixels PX2 arranged parallel to the first diagonal direction R1 may be alternately arranged in an adjacent third column 3M, the third pixels PX3 may be arranged at predetermined intervals in an adjacent fourth column 4M, and this arrangement of pixels may be repeated up to the M^{th} column.

The third pixel PX3 may be larger than the first pixel PX1 and the second pixel PX2.

The separation opening OPN2A may be located between the first pixel PX1 and the third pixel PX3 or between the second pixel PX2 and the third pixel PX3 to correspond to each side of the third light emitting area EA3, so as to surround the light emitting area of one third pixel PX3. The separation opening OPN2B may be located in parallel between the first pixel PX1 and the second pixel PX2.

Although not shown, separation patterns may be located in the separation openings OPN2A, OPN2B.

The light emitting member EM and the common electrode E2 between adjacent pixels may be short-circuited by the separation openings OPN2A and OPN2B, thereby reducing leakage current and stably driving a high-resolution display device.

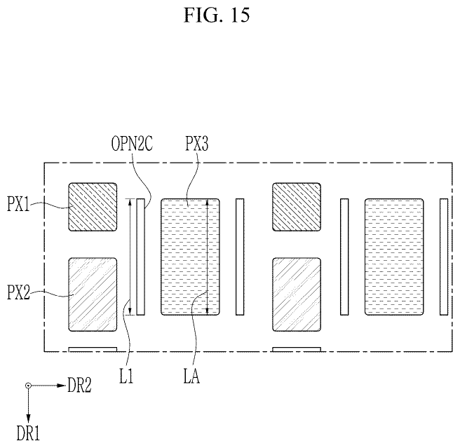

Referring to FIG. 15, arrangement of the pixels of the display device according to an embodiment is similar to the arrangement of the pixels of the display device according to the embodiment previously shown in FIG. 3.

The plurality of first pixels PX1 and the plurality of second pixels PX2 may be alternately arranged along the first direction DR1. The third pixel PX3 may be arranged to be spaced apart from the first pixel PX1 and the second pixel PX2 at predetermined intervals along the second direction DR2.

Each of the first pixel PX1, the second pixel PX2, and the third pixel PX3 may emit light of different wavelengths.

According to an embodiment, a driving voltage of the third pixel PX3 may be greater than that of the first and second pixels PX1 and PX2.

According to an embodiment, each of the first pixel PX1, the second pixel PX2, and the third pixel PX3 may have different sizes.

The separation opening OPN2C may be located between the first pixel PX1 and the third pixel PX3, or between the second pixel PX2 and the third pixel PX3. The separation opening OPN2C may not be located between the first pixel PX1 and the second pixel PX2.

A length L1 of the separation opening OPN2C may be substantially equal to a length LA of the third pixel PX3.

Although not shown, a separation pattern may be located in the separation opening OPN2C.

By the separation opening OPN2C, common layers between the first pixel PX1 and the third pixel PX3, or between the second pixel PX2 and the third pixel PX3 (for example, the light emitting member EM and the common electrode E2 between adjacent pixels) may be short-circuited, thereby reducing the leakage current and stably driving high-resolution display devices.

The separation opening OPN2C may not be located between the first pixel PX1 and the second pixel PX2, which are driven at a relatively low driving voltage and have a relatively small effect of leakage current. Accordingly, a voltage drop in the common voltage applied to the common electrode E2 may be prevented.

Many features of the display device and the manufacturing method of the display device according to the previously described embodiments are applicable to the display device according to an embodiment.

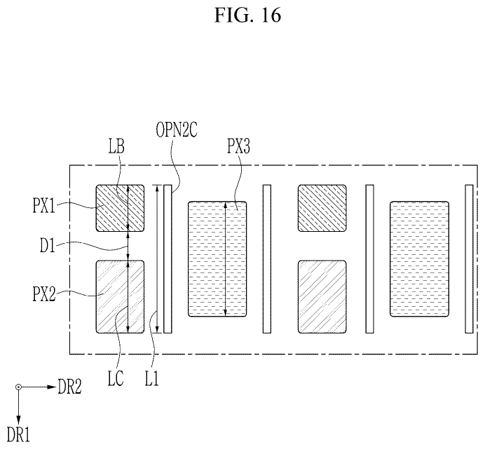

Referring to FIG. 16, the display device according to an embodiment is similar to the display device according to the embodiment described with reference to FIG. 15.

Referring to FIG. 16, a length L1 of the separation opening OPN2C may be substantially the same as or greater than a sum of a length LB of the first pixel PX1, a length LC of the second pixel PX2, and a distance D1 between the first pixel PX1 and the second pixel PX2. In addition, the length L1 of the separation opening OPN2C may be greater than a length of the third pixel PX3.

Although not shown, a separation pattern may be located in the separation opening OPN2C.

The separation opening OPN2C may be formed between the first pixel PX1 and the third pixel PX3, or between the second pixel PX2 and the third pixel PX3 along the first direction DR1, thereby reducing the leakage current between the third pixel PX3 and the first and second pixels PX1 and PX2.

In addition, the opening OPN2C may not be located between the first pixel PX1 and the second pixel PX2, which are driven at a relatively low driving voltage and have a relatively small effect of leakage current. Accordingly, a voltage drop in the common voltage applied to the common electrode E2 may be prevented.

Many features of the display device and the manufacturing method of the display device according to the previously described embodiments are applicable to the display device according to an embodiment.

The display device according to embodiments may be applied to various electronic devices. An electronic device according to an embodiment may include the display device, and may further include modules or devices having additional functions other than the display device.

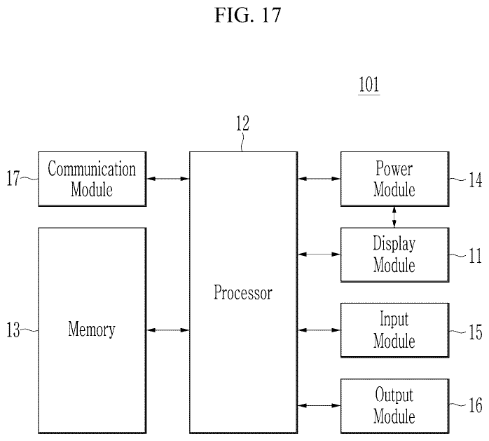

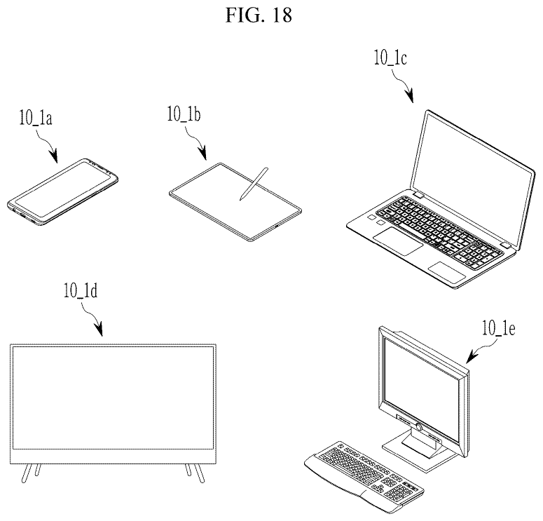

Referring to FIG. 17 to FIG. 20, an electronic device according to an embodiment will be described. FIG. 17 is a block diagram of an electronic device according to an embodiment, and FIGS. 18 to 20 are schematic views of electronic devices according to various embodiments.

Referring to FIG. 17, the electronic device 101 according to an embodiment may include a display module 11, a processor 12, a memory 13, and a power module 14. The electronic device 101 may further include an input module 14, a non-visual output module 15, and/or a communication module 16.

The electronic device 101 may output various information in the form of images through the display module 11. When the processor 12 executes an application stored in the memory 13, image information provided by the application may be provided to a user through the display module 11. The power module 14 may include a power supply module such as a power adapter or a battery device, and a power conversion module that converts power supplied by the power supply module to generate power necessary for operation of the electronic device 101. The input module 14 may provide input information to the processor 12 and/or the display module 11. The non-image output module 15 may receive non-image information from the processor 12, for example, sound, haptic, or light information, and provide it to the user. The communication module 16 is a module responsible for transmitting and receiving information between the electronic device 101 and external devices, and may include a receiver and a transmitter.

At least one of the components of the above-described electronic device 101 may be included in the display device according to the above-described embodiments. Also, some of the individual modules that are functionally included in one module may be included in the display device, and other parts may be provided separately from the display device. For example, the display device may include the display module 11, and the processor 12, memory 13, and power module 14 may be provided in the form of other devices within the electronic device 101 that is not the display device.

FIGS. 18 to 20 illustrate examples of various electronic devices to which the display device according to the embodiments may be applied.

FIG. 18 illustrates a smartphone 10_1a, a tablet PC 10_1b, a laptop 10_1c, a TV 10_1d, and a desktop monitor 10_1e as examples of electronic devices.

The smartphone 10_1a may include an input module such as a touch sensor and a communication module in addition to the display module 11. The smartphone 10_1a may process information received through the communication module or other input modules to display information through the display module of the display device.

A tablet PC 10_1b, a laptop 10_1c, a TV 10_1d, and a desktop monitor 10_1e may include a display module and an input module similar to a smartphone 10_1a, and may further include a communication module in some cases.

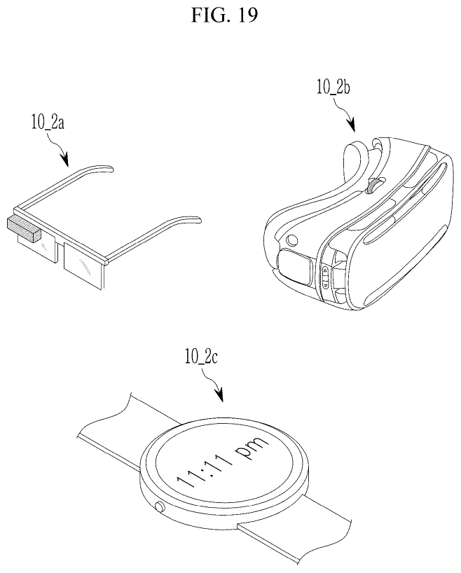

FIG. 19 illustrates an example where an electronic device including a display module is applied to a wearable electronic device. The wearable electronic device may be smart glasses 10_2a, a head-mounted display 10_2b, a smart watch 10_2c, or the like.

The smart glasses 10_2a and the head-mounted display 10_2b may include a display module that emits display images and a reflector that reflects the emitted display images to provide to the user's eyes, and through this, the smart glasses 10_2a and the head-mounted display 10_2b may provide virtual reality or augmented reality screens to the user.

The smart watch 10_2c includes a biosensor as an input device, and can provide biometric information recognized through the biosensor to the user through the display module.

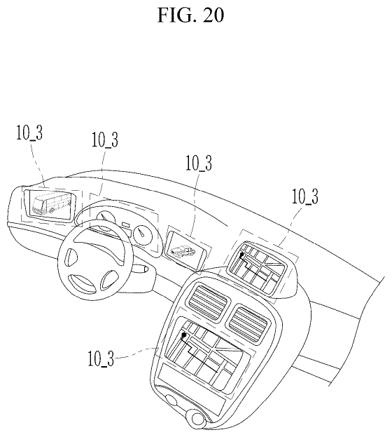

FIG. 20 illustrates an example where an electronic device including a display module is applied to a vehicle. For example, the electronic device 10_3 may be applied to a vehicle instrument panel, a center fascia, or may be applied to a CID (Center Information Display) placed on a vehicle dashboard or a room mirror display replacing a side mirror.

Although the embodiments of the present disclosure have been described in detail above, it is understood that the scope of the present disclosure is not limited to the disclosed embodiments. On the contrary, it is intended to cover various modifications and equivalent arrangements included within the spirit and scope of the appended claims.

What is claimed is:

1. A display device including a display area having a plurality of pixels and a non-display area surrounding the display area, the display device comprising:
a transistor located on a first substrate in the display area;
a pixel electrode connected to the transistor;
a light emitting member on the pixel electrode;
a common electrode on the light emitting member;
a planarization layer having a substantially uniform thickness and located between the transistor and the pixel electrode in the display area;
a pixel defining layer on the pixel electrode; and
a dam located on the first substrate in the non-display area,
wherein the dam includes a lower layer including a same layer as the planarization layer and an upper layer including a same layer as the pixel defining layer, and
wherein the pixel defining layer has a separation opening located between two adjacent pixels of the plurality of pixels.

2. The display device of claim 1, wherein
the non-display area includes a pad region including a pad portion, and
the planarization layer is removed in the pad region.

3. The display device of claim 1, wherein
a first thickness of the planarization layer in the display area is substantially equal to a second thickness of the lower layer of the dam, and
a third thickness of the pixel defining layer in the display area is substantially equal to a fourth thickness of the upper layer of the dam.

4. The display device of claim 3, wherein
a first width of the lower layer of the dam is greater than a second width of the upper layer of the dam, and
a sidewall of the lower layer of the dam includes two portions having different slopes.

5. The display device of claim 2, further comprising:
a sealant located between the dam and the pad region on the first substrate.

6. The display device of claim 5, wherein
the planarization layer is not located under the sealant.

7. The display device of claim 6, further comprising:
a second substrate bonded to the first substrate through the sealant and opposite to the first substrate.

8. The display device of claim 1, further comprising:
a separation pattern separated from the common electrode and located in the separation opening.

9. The display device of claim 8, wherein
the separation pattern further includes a portion separated from the light emitting member.

10. The display device of claim 1, wherein
the separation opening is formed in a portion of the planarization layer.

11. The display device of claim 10, further comprising:
a separation pattern separated from the common electrode and located in the separation opening.

12. The display device of claim 11, further comprising:
the separation pattern further includes a portion separated from the light emitting member.

13. A manufacturing method of a display device including a display area having a plurality of pixels and a non-display area surrounding the display area, the manufacturing method comprising:
forming a planarization layer on a transistor in the display area and a preliminary lower layer of a dam in the non-display area;
forming a pixel electrode connected to the transistor in the display area;
forming a pixel defining layer on the pixel electrode in the display area and a preliminary upper layer of the dam in the non-display area; and
forming the dam in the non-display area and a separation opening in the display area simultaneously by etching the preliminary lower layer and the pixel defining layer using an etching mask layer.

14. The manufacturing method of claim 13, wherein
the etching mask layer covers the preliminary lower layer and the preliminary upper layer of the dam.

15. The manufacturing method of claim 14, wherein
a first thickness of the planarization layer in the display area is substantially equal to a second thickness of a lower layer of the dam, and
a third thickness of the pixel defining layer in the display area is substantially equal to a fourth thickness of an upper layer of the dam.

16. The manufacturing method of claim 15, wherein
a first width of the lower layer of the dam is greater than a second width of the upper layer of the dam, and
a sidewall of the lower layer of the dam includes two portions having different slopes.

17. The manufacturing method of claim 13, further comprising:
forming a light emitting member and a common electrode on the pixel electrode in the display area, and a separation pattern separated from the common electrode in the separation opening.

18. The manufacturing method of claim 17, wherein
the separation pattern further includes a portion separated from the light emitting member.

19. The manufacturing method of claim 13, wherein
the forming the separation opening includes etching the pixel defining layer and a portion of the planarization layer.

20. An electronic device, comprising:
a display module; and
a processor connected to the display module and controlling the display module,
wherein the display module includes a display device including a display area having a plurality of pixels and a non-display area surrounding the display area, and
wherein the display device comprises
a transistor located on a first substrate in the display area;
a pixel electrode connected to the transistor;
a light emitting member on the pixel electrode;
a common electrode on the light emitting member;
a planarization layer having a substantially uniform thickness and located between the transistor and the pixel electrode in the display area;
a pixel defining layer on the pixel electrode; and
a dam located on the first substrate in the non-display area,
wherein the dam includes a lower layer including a same layer as the planarization layer and an upper layer including a same layer as the pixel defining layer, and
wherein the pixel defining layer has a separation opening located between two adjacent pixels of the plurality of pixels.
